(19) United States
(12) Patent Application Publication
(10) Pub. No.: US 2026/0221197 A1
(43) Pub. Date: Jul. 30, 2026

(54) DATA LINE STATABLIZATION WITH KNOCK-OUT EFFECT REDUCTION

(71) Applicant: Micron Technology, Inc., Boise, ID (US)

(72) Inventors: Ottavio Nuccilli, AIELLI (IT); Andrea D'alessandro, AVEZZANO (IT)

(73) Assignee: Micron Technology, Inc., Boise, ID (US)

(21) Appl. No.: 19/449,264

(22) Filed: Jan. 14, 2026

Related U.S. Application Data
(60) Provisional application No. 63/750,110, filed on Jan. 27, 2025.

(51) Int. Cl. G11C 16/24; G11C 16/04; G11C 16/08; G11C 16/26; G11C 16/34

(52) U.S. Cl. CPC G11C 16/24; G11C 16/0483; G11C 16/08; G11C 16/26; G11C 16/3459

(57) ABSTRACT

Methods, systems, and devices for techniques for reducing or preventing data knock out are described. A memory device includes an array of memory cells; data lines coupled to the array of memory cells; one or more sense amplifiers coupled to the data lines; and a memory controller. The memory controller is configured to perform, for data sensing operations comprising sensing at least at a first sensing level and a second sensing level: causing precharging of the data lines, causing the one or more sense amplifiers to sense, at the first sensing level, the data lines to obtain data stored in the array of memory cells, and keeping the data lines pre-charged even if at least one of the data lines is not sensed at the second sensing level.

### RELATED APPLICATIONS

This application claims priority to U.S. Provisional Application No. 63/750,110, filed on January 27, 2025, entitled “DATA LINE STABILIZATION WITH KNOCK-OUT EFFECT REDUCTION.” The contents of U.S. Provisional Application No. 63/750,110 are incorporated herein in their entirety for all purposes.

### TECHNICAL FIELD

This disclosure relates to one or more systems for memory, including techniques for reducing the interference between data lines due to data line knock-out.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4 illustrates an example “forward read” operation and an example “reverse read” operation, in accordance with examples as disclosed herein.

FIG. 5 illustrates data line interference introduced by data line knock-out due to the coupling capacitance between data lines.

FIG. 6 illustrates a circuit configured to reduce or avoid data line knock-out by keeping the data lines pre-charged even if some data lines are not sensed at the next sensing levels, in accordance with examples as disclosed herein.

FIG. 7 illustrates a timing diagram illustrating read operations performed by circuits configured to reduce or avoid data line knock-out by keeping the data lines pre-charged even if some data lines are not sensed at the next sensing levels, in accordance with examples as disclosed herein.

FIGS. 8A and 8B illustrate flowcharts showing a method or methods that support techniques for reducing data line interference due to knock-out in accordance with examples as disclosed herein.

### DETAILED DESCRIPTION

Memory devices have data lines such as bit lines. A bit line is coupled to a string of memory cells of a memory device, as described in more detail below. Multiple bit lines in a memory device may be increasingly coupled to one another as the device size becomes smaller and smaller nowadays. During certain memory device operations, such as a read operation or a program verify operation, the memory controller may select a memory cell and cause the data line coupled to the selected memory cell to be pre-charged. During a read operation of the selected memory cell, if the memory controller determines that the selected memory cell’s threshold voltage satisfies a particular read level (also referred to as the sensing level or the word line voltage level), the data line coupled to the selected memory cell may be discharged to a source voltage (e.g., a ground voltage). The data line (e.g., bit line) is thus deactivated (also referred to as “knocked out”). The memory controller, in the subsequent read operations, does not read memory cells that have been knocked out. The data line that is knocked out does not sink current. The selected memory cell coupled to a knocked-out data line is thus not sensed again, because the memory controller has already determined that the data stored in the selected memory cell was read successfully.

As the memory device becomes more compact, the memory device has a greater number of memory cells so it has a larger memory storage capacity. As a result, data lines (e.g., bit lines) may become closer to one another. Neighboring data lines have coupling capacitance between them. As described above, when a data line is knocked out, it is no longer pre-charged but instead discharged to a source voltage (e.g., 0V or a predetermined small voltage). Because of the coupling capacitance between data lines, the knocked-out data lines may disturb or interfere with the adjacent data lines, which may be still pre-charged. Moreover, as described above, a data line oftentimes is coupled to a string of memory cells, which may include many memory cells (e.g., tens, hundreds, or thousands). Therefore, a data line may have a large associated capacitance. Furthermore, a data line is usually coupled to the page buffer (e.g., including a sense amplifier) on one end, and coupled to a source plate on the other end. The source plate is usually regulated, e.g., by a voltage regulator, at a predetermined low voltage (e.g., at the electrical ground voltage). Thus, because the data line has a large associated capacitance, data line knock-out may cause the source plate to have a voltage bounce, because the pre-charged data line and the source plate have different voltages.

Therefore, knocked-out data lines may not only interfere with the adjacent data lines but also cause undesired source plate voltage disturbance. The interference of the adjacent data lines prevents, makes it difficult for, or at least delays, the next data sensing operation to be performed. For instance, the next data sensing operation may be delayed because interfered adjacent data lines need to be stabilized before the next data sensing operation can be performed at a corresponding next sensing level. Similarly, the source plate voltage disturbance may be significant enough such that it requires extra time for the source plate to return to its regulated voltage. Accordingly, the knocked-out data lines may induce time delays in read operations to allow the victim lines and the source plate to recover from the interference. The time delays in turn impact the overall performance of data sensing operations, like the read operation.

Technologies described in the present disclosure provide a memory device that include a memory controller configured to prevent or reduce the data line knock-out. The controller is configured to cause pre-charging of the data lines, cause the sense amplifier to sense, at a first sensing level, the data lines to obtain data stored on the memory cells, and keep the data lines pre-charged even if at least one of the data line is not sensed at the next sensing level. Therefore, the technologies described herein avoid data line knock-out. By avoiding data line knock-out, the present disclosure provides technologies that can reduce or minimize the interference between data lines (e.g., bit lines), reduce or eliminate the source plate disturbance, and reduces the load driven by a boost regulator for an internal temporary cache (tc) node. In turn, the technologies presented herein reduce power consumption of the circuit and improve the data sensing operational performance, without the need to add additional hardware to the existing memory device. The details of the embodiments of the aforementioned technologies are described below.

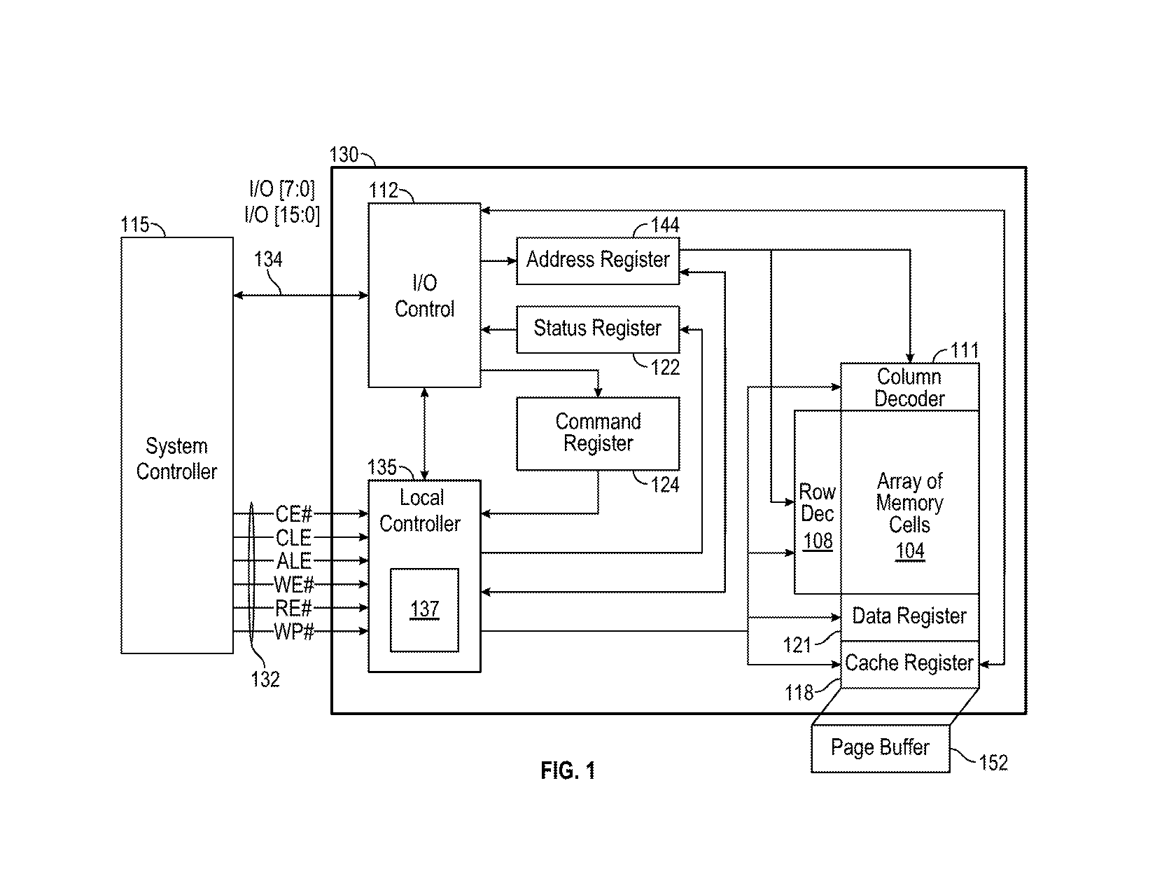

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

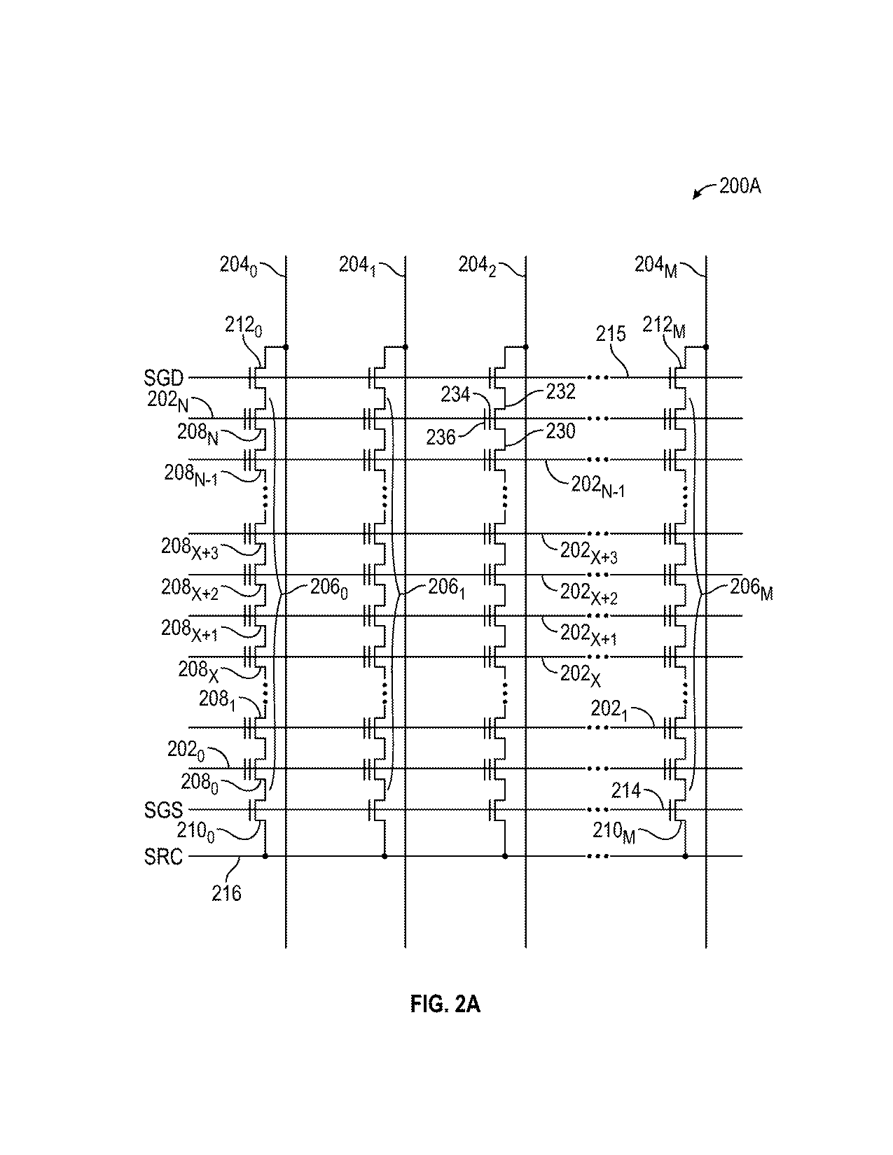

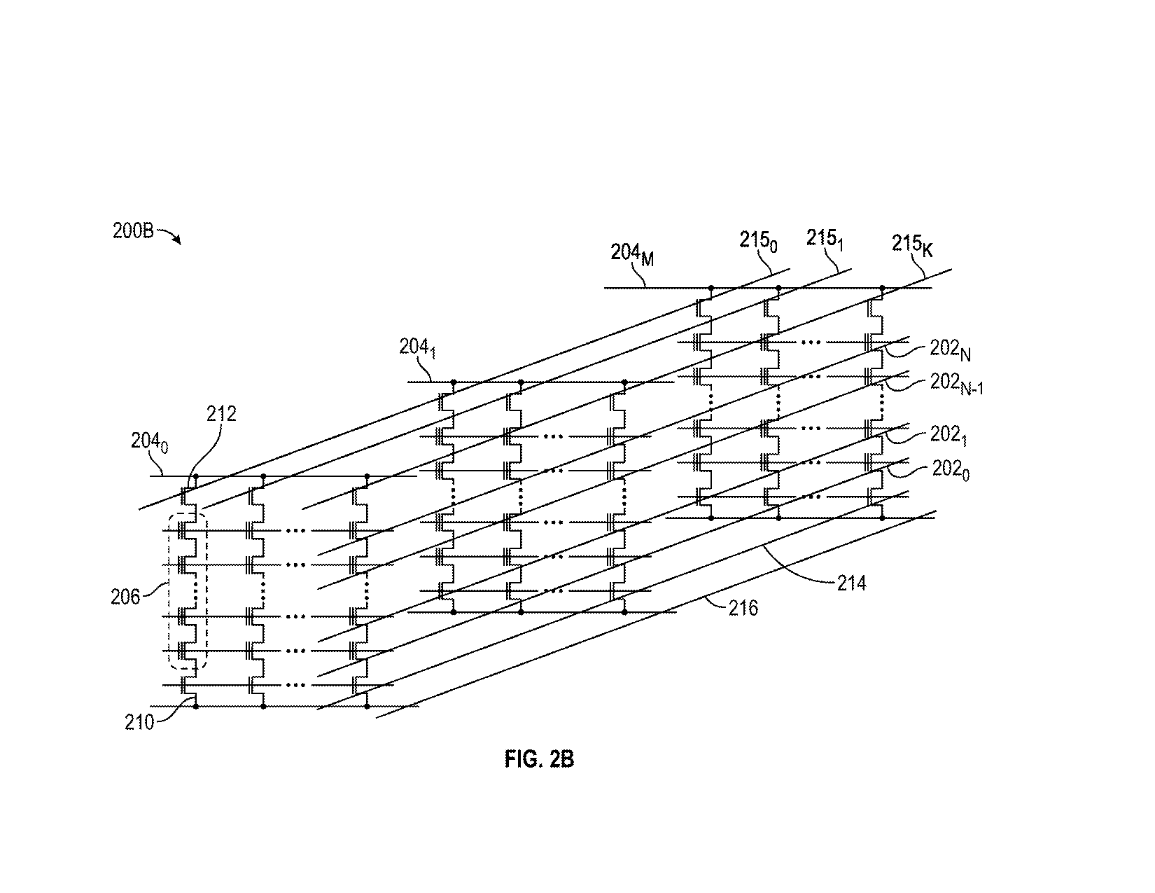

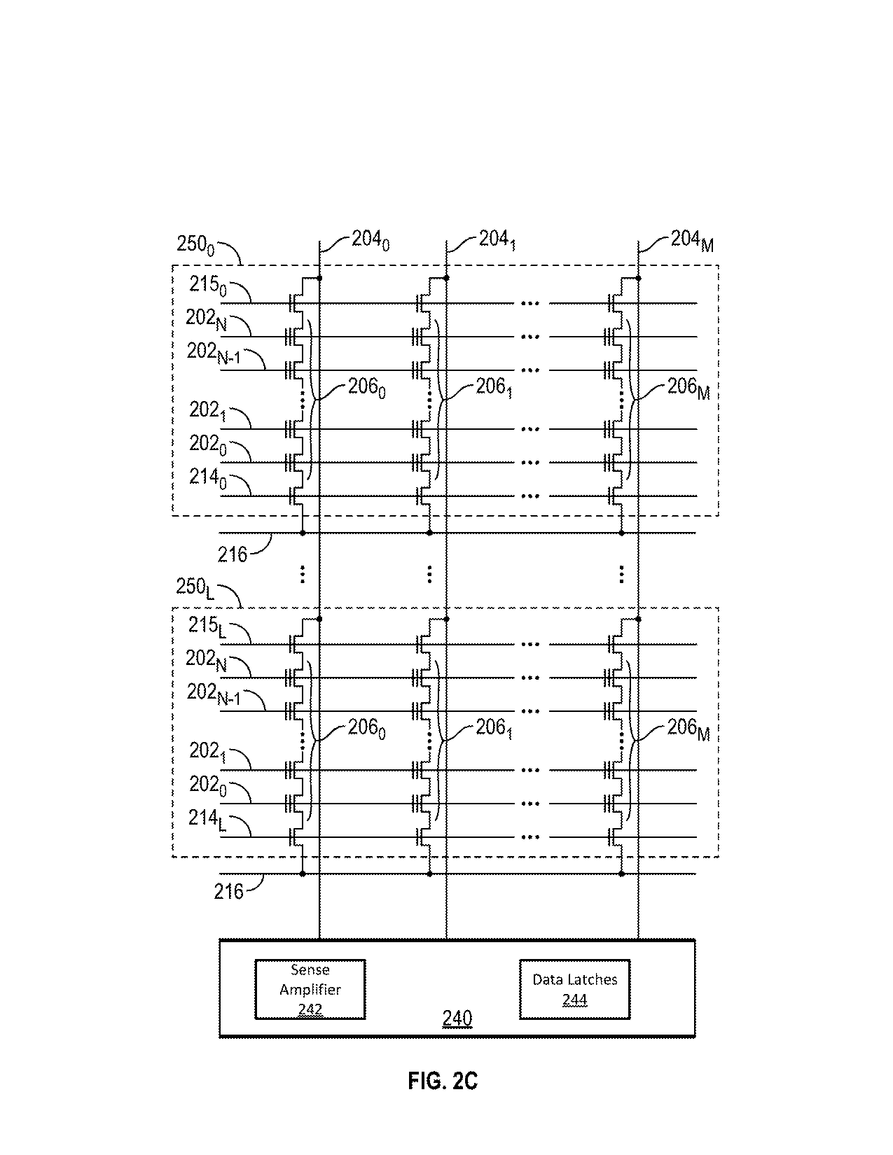

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. As described below in connection with FIG. 2C, in some examples, page buffer 152 includes a buffer portion 240 having a sense amplifier 242 and one or more data latches 244. The data latches 244 may store data sensed by the sense amplifier 242. In one example, data latches 244 can be a part of cache register 118 and/or data register 121. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀to 202_{N}, and data lines, such as bit lines 204₀to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N}and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a larger storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Word lines 202 and select lines 214 and 215 of one block of memory cells 250 can have no direct connection to word lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifier 242) for sensing data values indicated on respective bit lines 204. In some examples, buffer portion 240 can also include one or more data latches 244, which can be a part of cache registers 118 and/or data registers 121 as described above in FIG. 1. Data latches 244 can store data values sensed from memory cells selected for performing data sensing operations including read operations and/or program verify operations. For instance, during a read or program verify operation, sense amplifier 242 can sense, at a particular sense level, the current flowing through a particular bit line coupled to a memory cell selected for sensing. The sensed data can be integrated and digitized. The digitized data can be stored in data latches 244.

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

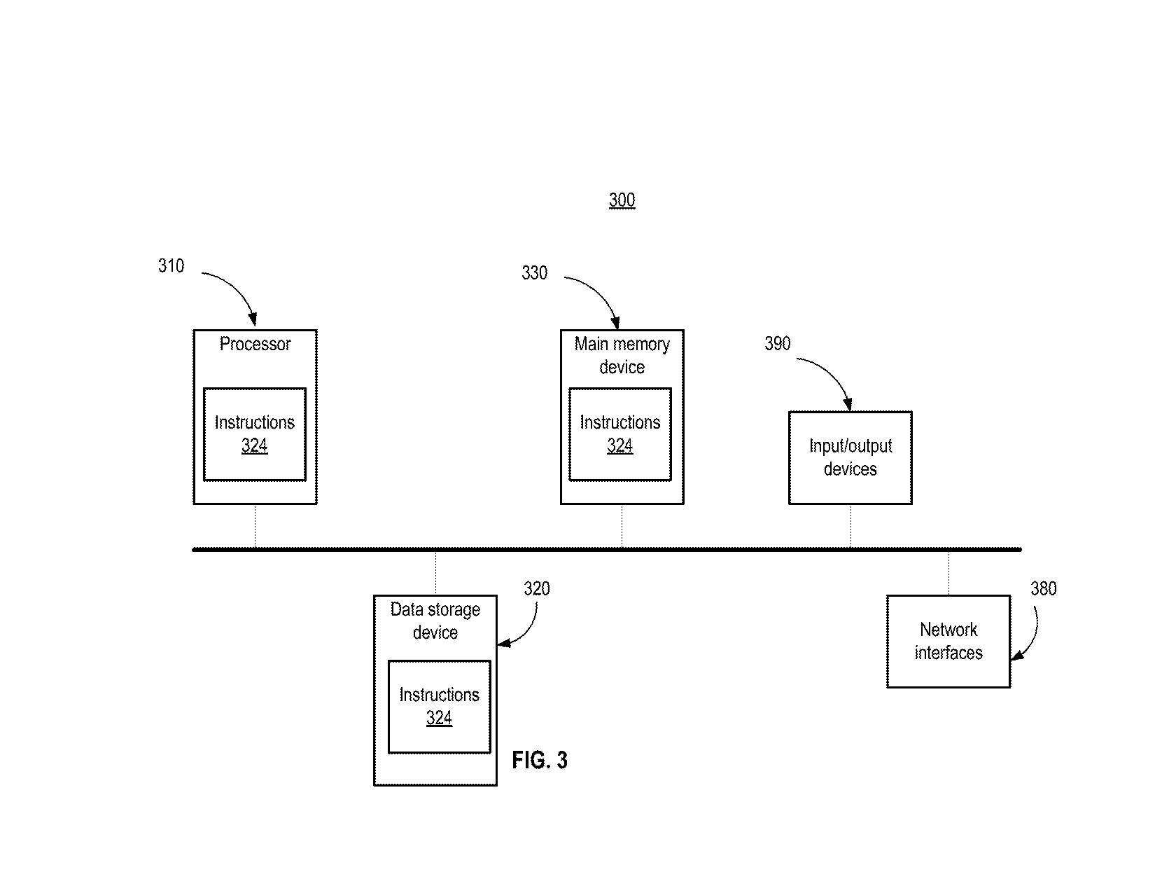

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-8, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-8 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-8. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

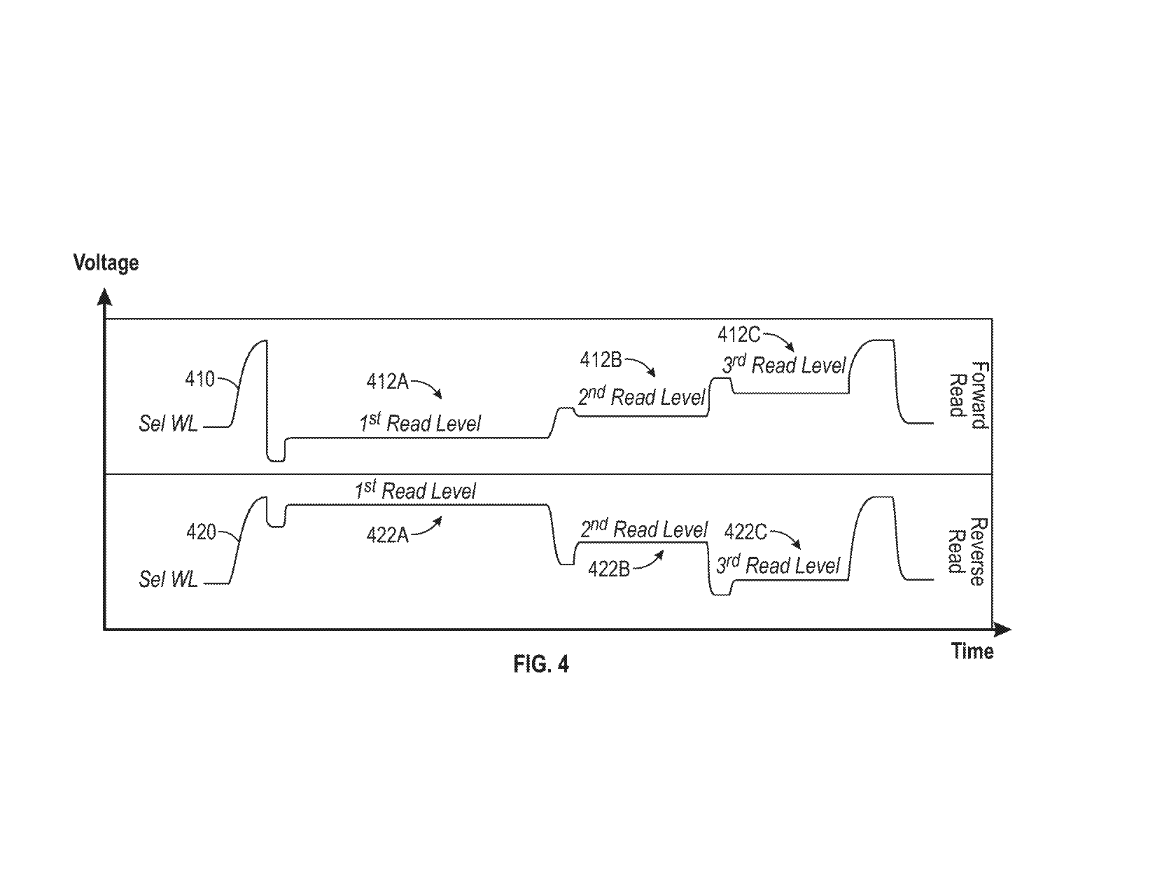

As described above, the technologies described in the present disclosure can be applied to improve the data sensing operations of a memory device. The data sensing operations include memory read operations and/or program verify operations. The examples in this disclosure use memory read operations for illustration. It is understood, however, the descriptions of the technologies herein can also be used for program verify operations in a same or similar manner. A memory read operation may be a “forward read” operation or a “reverse read” operation. FIG. 4 illustrates example timing sequences 410 and 420 corresponding to a “forward read” operation and a “reverse read” operation, in accordance with examples as disclosed herein. Each of the timing sequences 410 and 420 may be a read sequence containing multiple strobes. Each of the timing sequences 410 and 420 may represent a read operation of a memory page (e.g., the lower page LP, the upper page UP, the extra page XP, the top page TP, etc.).

With reference to FIG. 4, timing sequence 410 illustrates a read sequence using a forward read method. In a forward read method, the sensing level used to code a specific page (e.g., LP, UP, XP, or TP) starts from the lowest sensing level and increases to the highest sensing level. The sensing level is also referred to as the read level. As shown in FIG. 4, in a forward read timing sequence 410, the first read level 412A is the lowest, the second read level 412B is greater than the first read level 412A, and the third read level 412C is greater than the second read level 412C. Each of the read levels 412 corresponds to a word line voltage applied to the word line of a selected memory cell that is being sensed. In a reverse read timing sequence 420, the first read level 422A is the highest, the second read level 422B is less than the first read level 422A, and the third read level 422C is less than the second read level 422B. Each of the read levels 422 corresponds to a word line voltage applied to the word line of a selected memory cell that is being sensed. While FIG. 4 illustrates three read levels in either the forward read timing sequence 410 or the reverse read timing sequence 420, it is understood that more or fewer read levels may be used in a read operation.

Compared to forward read, reverse read has several advantages. For example, it may potentially yield a better Read Window Budget (RWB) than forward read. This is because applying a higher voltage to memory cells can reduce the interference caused by the prior reads in the read operation (e.g., reduce the read disturb) and thus reduce the threshold voltage shift. The memory cells’ threshold voltages (Vt) distribution may therefore be narrower, resulting in a wider RWB. Reverse read may also lead to faster memory read time. This can be attributed to the fact that while the voltage level of each data sensing operation (e.g., each strobe) is applied from high to low, the corresponding bit line’s voltage reaches its final value more rapidly, thus expediting the stabilization process of the bit line. On the contrary, if the voltage level of each strobe is applied from low to high, the time required for bit line stabilization may be prolonged. In addition, as shown in FIG. 4, in a reverse read sequence 420, the word line voltage ramps up to a high level and does not need to be reduced, or reduced significantly, to reach the first read level 422A. In contrast, in a forward read sequence 410, the word line voltage ramps up to a high level and needs to be reduced significantly to reach the first read level 412A. Accordingly, the reverse read method may potentially improve speed of the operation and in turn the overall read operation performance.

Regardless of forward read or reverse read, at each sensing level, a data sensing operation (e.g., read operation or program verify operation) is performed. Each sensing level corresponds to a different word line bias voltage applied to word line of a memory cell selected for data sensing. For different types of memory devices, the memory controller may apply different numbers of word line bias voltage levels for performing different numbers of data sensing operations. For example, for sensing memory cells of a TLC memory device, the memory controller may apply seven different word line bias levels grouped in a 2-3-2 sequence. For sensing memory cells of a QLC memory device, the memory controller may apply fifteen different word line bias levels grouped in a 4-4-3-4 sequence. Thus, for TLC memory cell sensing, seven data sensing operations are performed at seven different sensing levels (e.g., different read levels or word line bias levels). For QLC memory cell sensing, fifteen data sensing operations are performed at fifteen different sensing levels (e.g., different read levels or word line bias levels).

During a data sensing operation at a particular sensing level, the memory controller causes a particular word line bias voltage to be applied to a memory cell selected for sensing. Depending on the threshold voltage of the memory cell (e.g., denoted as V_{th, cell}), the selected memory cell may or may not be activated (e.g., turned on). If the selected memory cell is activated (e.g., turned on), electrical current flows through the bit line coupled to the selected memory cell. If the selected memory cell is not activated, no or negligible current flows through the bit line coupled to the selected memory cell. A sense amplifier senses the current flowing through the bit line, integrates the current by an integration circuit, and stores an analog voltage representing the integration result. The memory controller may also cause the sense amplifier to convert the analog voltage to digital data, representing the data value stored in the selected memory cell. If the selected memory cell was not activated at the particular sensing level, the memory controller causes a next data sensing operation to be performed, by applying a next sensing level (e.g., a next read level of word line bias voltage) and repeating the data sensing using the sense amplifier.

Data line (e.g., bit line) knock-out may occur in both forward read operations and reverse read operations. During a read operation, a bit line is pre-charged. The word line bias voltages changes based on the different read levels (e.g., increases or decreases depending on whether it is a forward read operation or reverse read operation). In a forward read operation, if the selected memory cell has a threshold voltage that is greater than the particular read level, the selected memory cell remains off (e.g., the word line bias voltage is not large enough to turn on the memory cell and therefore there is no or negligible current flowing through the bit line). Correspondingly, the digital value stored in the sense amplifier (SA) is 1(denoted by SA=1). If the selected memory cell has a threshold voltage that is less than or equal to the particular read level, the selected memory cell is activated (e.g., turned on) and current flows through the bit line. The sense amplifier senses the current and correspondingly, the digital value stored in the sense amplifier (SA) is 0 (denoted by SA=0). For a reverse read operation, the corresponding SA values are the opposite. In a reverse read operation, the maximum word line bias voltage is applied initially to the selected memory cells, so the selected memory cell turns on initially to conduct current. In a reverse read operation, if a selected memory cell has a threshold voltage that is less than the particular read level, the selected memory cell turns on and the digital value stored in the sense amplifier is 1(denoted by SA=1). If a selected memory cell has a threshold voltage that is still greater than or equal to the particular read level, the selected memory cell remains deactivated (e.g., remain off) and the digital value stored in the sense amplifier is 0 (denoted by SA=0).

The memory controller may determine the stored data value in the selected memory cell by determining whether the selected memory cell’s threshold voltage satisfies the read level. No further data sensing operations (e.g., reading or program verifying) are needed for the selected memory cell if the selected memory cell’s threshold voltage satisfies the read level. For instance, in a forward read operation, if a particular read level is greater than the selected memory cell’s threshold voltage (i.e., read level > V_{th,cell}), no further data sensing operations are needed for this particular selected memory cell. In a reverse read operation, if a particular read level is less than the selected memory cell’s threshold voltage (i.e., read level < V_{th,cell}), no further data sensing operations are needed for this particular selected memory cell. In both of these two scenarios, the digital value stored in the sense amplifier (or a data latch in the page buffer) is zero (i.e., SA=0). Typically, upon determining that no further data sensing operations should be performed on the selected memory cell, the bit line coupled to the selected memory cell is knocked out. The sense amplifier is connected to the circuit path that pre-charges the bit line of the selected memory cell. The digital value stored in the sensing amplifier (or the data latches of the page buffer) can be used to determine if a bit line is knocked out. For instance, if SA=1, the bit line is pre-charged; and if SA=0, the bit line is knocked out (e.g., reduce to the source plate voltage).

In forward read operations, the knock-out (KO) allows to reduce the number of memory strings injecting current in the source plate as the word line voltage increases during the read operation. Therefore, in forward read operations, KO may improve the sensing accuracy (with reduced source voltage bounce) and reduce the power consumption. In reverse read operations, the first read level is the highest word line voltage and the current injected in the source plate is already the maximum possible for that specific memory page type. During the read operation, the word line voltage reduces and the number of memory strings injecting current to the source plate naturally decreases. Therefore, for reverse read operations, knock-out can be readily avoided. Knock-out can also be avoided or reduced in forward read operations if string current and power consumption requirements are not particularly high.

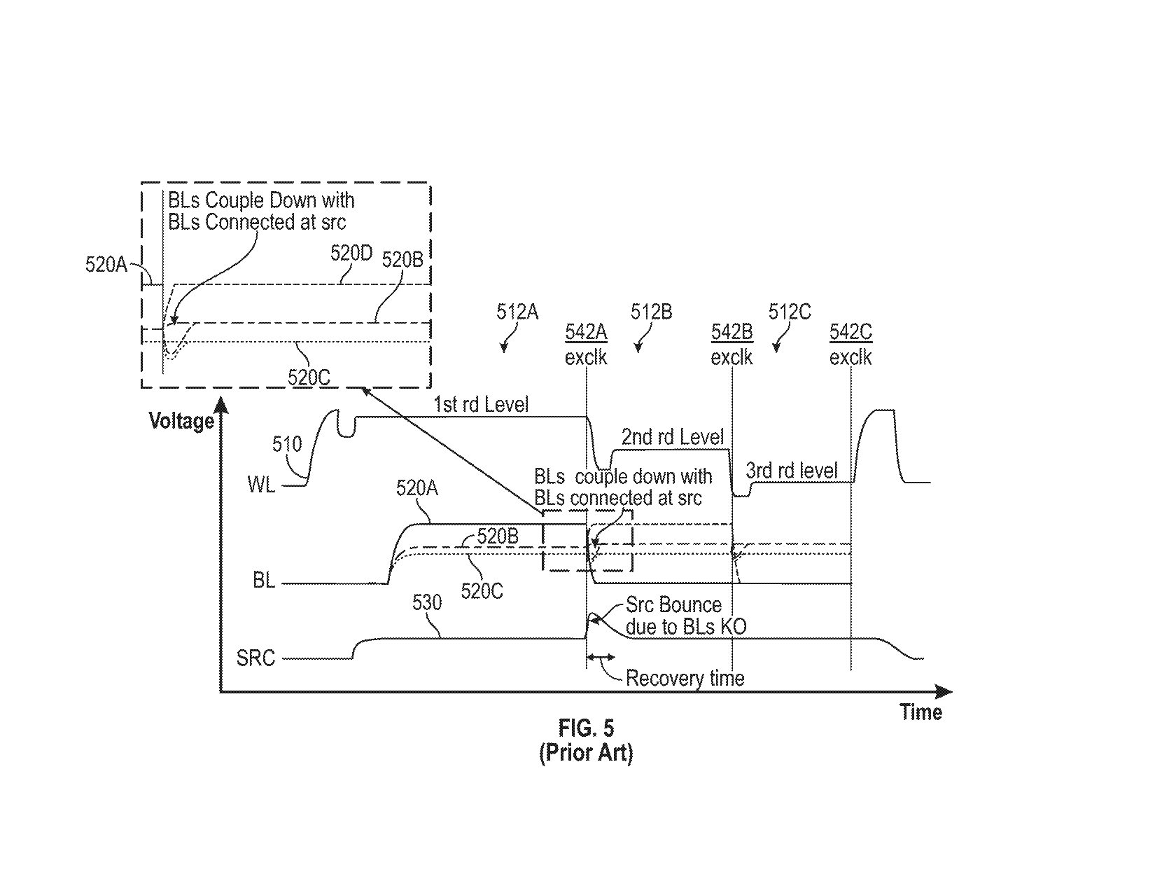

As described above, bit line knock-out may cause the interference of the adjacent bit lines and disturbance of the source plate. Such an impact is also illustrated in more detail below using FIG. 5. FIG. 5 illustrates data line interference introduced by data line knock-out due to coupling capacitance between data lines. In FIG. 5, a reverse read timing sequence 510 is illustrated. Sequence 510 is the same or similar to sequence 420 shown in FIG. 4. Thus, in reverse read timing sequence 510, the first read level 512A is the highest level, the second read level 512B is less than the first read level 512A, and the third read level 512C is less than the second read level 512B and is the lowest level among the three read levels 512A-512C. Each of the read levels 512A-512C corresponds to a word line voltage applied to the word line coupled to a selected memory cell that is being sensed in a particular data sensing operation. It is understood that while FIG. 5 only illustrates three read levels, more or fewer read levels may be applied (e.g., the controller may apply more or fewer levels of word line voltages to the word lines of selected memory cells).

FIG. 5 also illustrates several example timing diagrams of data lines such as bit lines 520A-520C. Bit lines 520A-520C may be adjacent bit lines such that they have capacitive coupling between one another. For instance, bit line 520A may be physically located in-between or near bit lines 520B and 520C, such that bit line 520A is capacitively coupled to bit line 520B and bit line 520C. As such, any transition of the voltage level of bit line 520A may cause interference or disturbance of bit line 520B and/or bit line 520C due to the capacitive coupling. This is further illustrated in FIG. 5 when the word line voltage moves from the first read level 512A to the second read level 512B. In this example, the memory cell coupled to bit line 520A may be read and the controller may determine that no further reading is needed for this particular memory cell (e.g., the voltage of first read level 512A is less than the threshold voltage of the particular memory cell). As a result, the controller may cause the bit line 520A to be knocked out, thereby reducing its voltage to the source plate voltage by connecting the bit line 520A to the source plate (e.g., SRC 216 in FIG. 2A). FIG. 5 thus illustrates that the voltage of bit line 520A reduces to a low level near the external clock event 542A, which triggers the transition from the first read level 512A to the second read level 512B. In FIG. 5, another two external clock events 542B and 542C trigger the transition from second read level 512B to third read level 512C and the transition from the third read level 512C to a recovery phase.

FIG. 5 also illustrates a zoom-in view of the impact of the voltage reduction of bit line 520A on adjacent bit lines 520B and 520C due to knock-out. As shown in the zoom-in view of FIG. 5, the voltage reduction of bit line 520A causes voltages of bit lines 520B and 520C to change as well due to the capacitive coupling between these adjacent bit lines. Bit lines 520B and 520C, in this example, are coupled to memory cells associated with bit line 520A that are knocked-out after the first read level 512A. But bit lines 520B and 520C should remain pre-charged so that the connected memory cells can be read again at the second read level 512B. The knock-out of bit line 520A, however, causes the interference or disturbance of the voltage levels of bit line 520B and 520C. As a result, the next read operation at the second read level 512B must wait until the bit lines 520B and 520C can recover their voltage levels to the respective pre-charged levels. The recovery causes time delay of the read operation. The same interference or disturbance may also occur at external clock events (e.g., 542B) when the read level changes again from the second read level 512B to the third read level 512C. Thus, knock-out of bit line 520A causes undesired voltage changes/transitions in the adjacent bit lines 520B and 520C, which in turn slows the read operation speed. Similarly, FIG. 5 shows that bit line 520D is pre-charged at the second read level 512B and knocked-out (e.g., discharged) at the third read level 512C. The transition from the second read level 512B to third read level 512C is triggered by external clock event 542B. As a result, there are similar interference or disturbance caused by knock-out bit line 520D.

FIG. 5 further illustrates the impact of the voltage change of bit line 520A on the source plate (denoted by SRC) due to knock-out. As described above, at or around external clock 542A, which triggers the word line voltage to transition from the first read level 512A to the second read level 512B, the voltage level of source plate 530 can be interfered or disturbed too. As shown in FIG. 5, the voltage level of the source plate 530 (SRC 530) may increase momentarily before it settles down again. Source plate 530 may be the same or similar as SRC 216 in FIG. 2, and may be connected to many bit lines (e.g., bit lines 520A-520C and other bit lines). Each of the bit lines connected to the source plate 530 may have large associated capacitance, and therefore, a transition in the bit line voltage caused by knock-out may cause the source plate 530 to have a voltage change (e.g., a voltage bounce as shown in FIG. 5). The source plate voltage changes due to bit line knock-out requires extra time for the source plate 530 to recover to its regulated voltage. Before the source plate 530 can recover, the read operation may not be performed, thereby also impacting the overall read operation performance.

In some examples, for instance, the extra time required for adjacent bit lines to recover and/or for the source plate to recover may be on the scale of microseconds. This means that the next level read operation cannot be performed until the recovery is complete. In a memory device, there may be many bit lines (e.g., thousands of bit lines). If many bit lines are knocked out, the read operation performance of the memory device may be significantly reduced due to the extra recovery time. In addition, bit line knock-out may impact the bit line stability of the next strobe (e.g., data sensing at the next read level), thereby reducing the performance accuracy of the read operations. The present disclosure provides technologies for reducing or eliminating knock-out of data lines and therefore improving on read operation performance to increase read accuracy and to reduce read time delay.

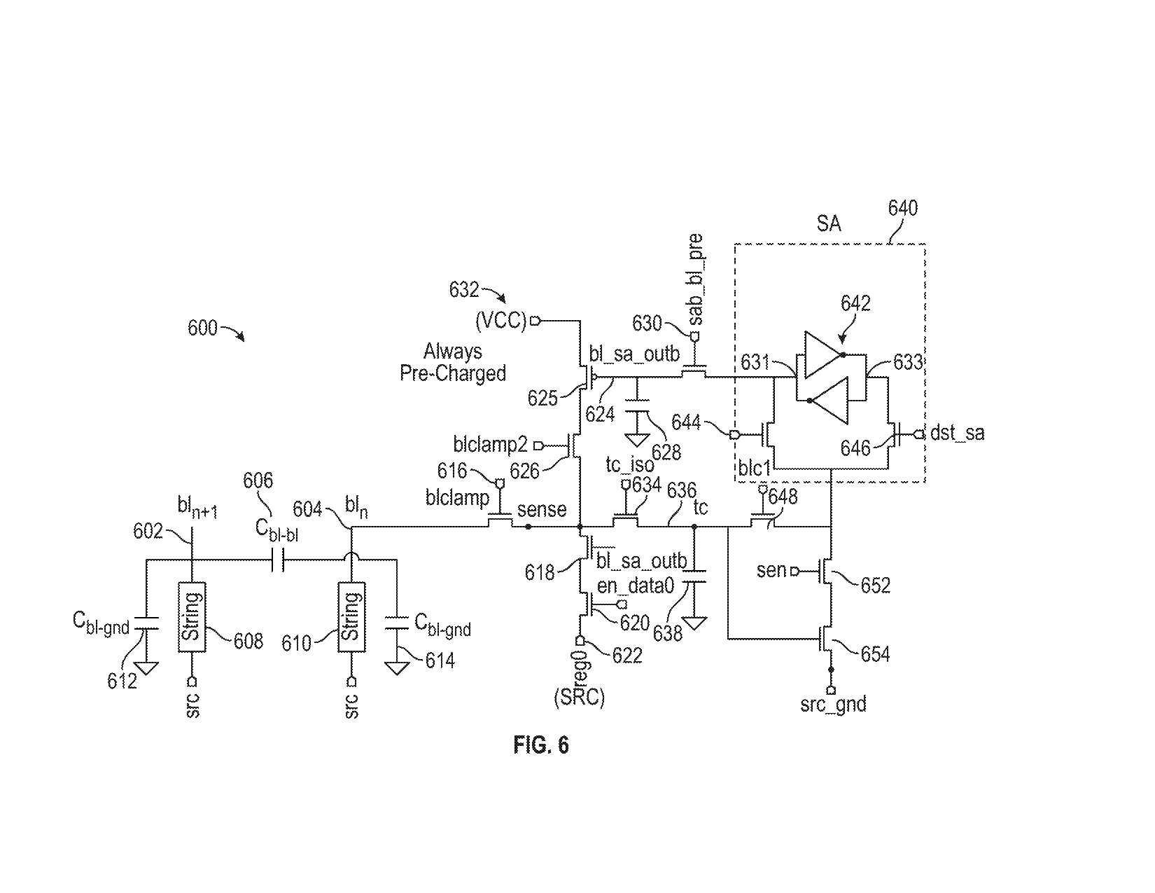

FIG. 6 illustrates a circuit 600 configured to reduce or avoid data line knock-out by keeping the data lines pre-charged even if some data lines are not sensed at the next sensing levels, in accordance with examples as disclosed herein. As shown in FIG. 6, circuit 600 may be a part of a memory device (e.g., device 130). For instance, circuit 600 may include a first part including a sense amplifier 640 and other switches, transistors, capacitors, etc. The first part of circuit 600 may be a part of a page buffer (e.g., page buffer 152 or buffer portion 240). For instance, sense amplifier 640 may be the same or similar to sense amplifier 242 in FIG. 2C. Other parts of the page buffer (e.g., data latches) may not be illustrated in circuit 600. The second part of circuit 600 may include multiple strings of memory cells (two such strings 608 and 610 are shown). Each of these strings of memory cells in circuit 600 may be the same as or similar to string 206 shown in FIGS. 2A-2C. Each of these strings of memory cells are connected to a corresponding data line. Two such data lines 602 and 604 are shown in FIG. 6. As described above, data lines may be bit lines in a NAND memory device. So the below discussion may refer to bit lines as the data lines using NAND memory device as an example. In FIG. 6, the data line 602 is denoted as bₗₙ₊₁ and data line 604 is denoted as bₗₙ. Data lines 602 and 604 can be adjacent bit lines such that they are capacitively coupled. The circuit 600 in FIG. 6 also shows some equivalent capacitances 606, 612, and 614 associated with the data lines 602 and 604. Operation of the circuit 600 is described next.

With reference still to FIG. 6, in some examples, a memory controller (e.g., the controller 135 or 115) is configured to perform one or more data sensing operations (e.g., a read operation or a program verify operation). The data sensing operations may include sensing at a plurality of sensing levels (e.g., a first sensing level, a second sensing level, etc.). Each sensing level may be different from other sensing levels. As described above, a sensing level corresponds to a word line voltage level of a particular memory cell selected to be sensed (e.g., read). Thus, the first sensing level may be different from the second sensing level (e.g., lower or higher depending on if a forward-read operation or a reverse-read operation is performed). A sensing level is also referred to as a read level in a read operation or program verify operation.

For performing data sensing operations, the memory controller can cause per-charging of the data lines. Using circuit 600 as an example, the memory controller (e.g., controller 115 or 135 shown in FIG. 1), can control one or more switches to pre-charge the data lines 602 and 604. In one example, to cause data line 604 (denoted as bₗₙ) to be pre-charged, the memory controller causes switch 616 (denoted as blclamp), switch 626 (denoted as blclamp2), and switch 625 to turn on. As a result, data line 604 is connected to the power supply 632 (denoted a VCC) and is therefore pre-charged (e.g., its voltage is pulled up to VCC). Other data lines (e.g., data line 602) can be similarly pre-charged. Circuit 600 as shown in FIG. 6 only illustrates switches 616, 625, and 626 for controlling data line 604. Other switches can be used to control other data lines (e.g., another set of two switches can be used to control the pull-up path for data line 602). Switch 626 is also referred to as a pre-charge clamp switch. Switch 616 is referred to as a bit line clamp switch.

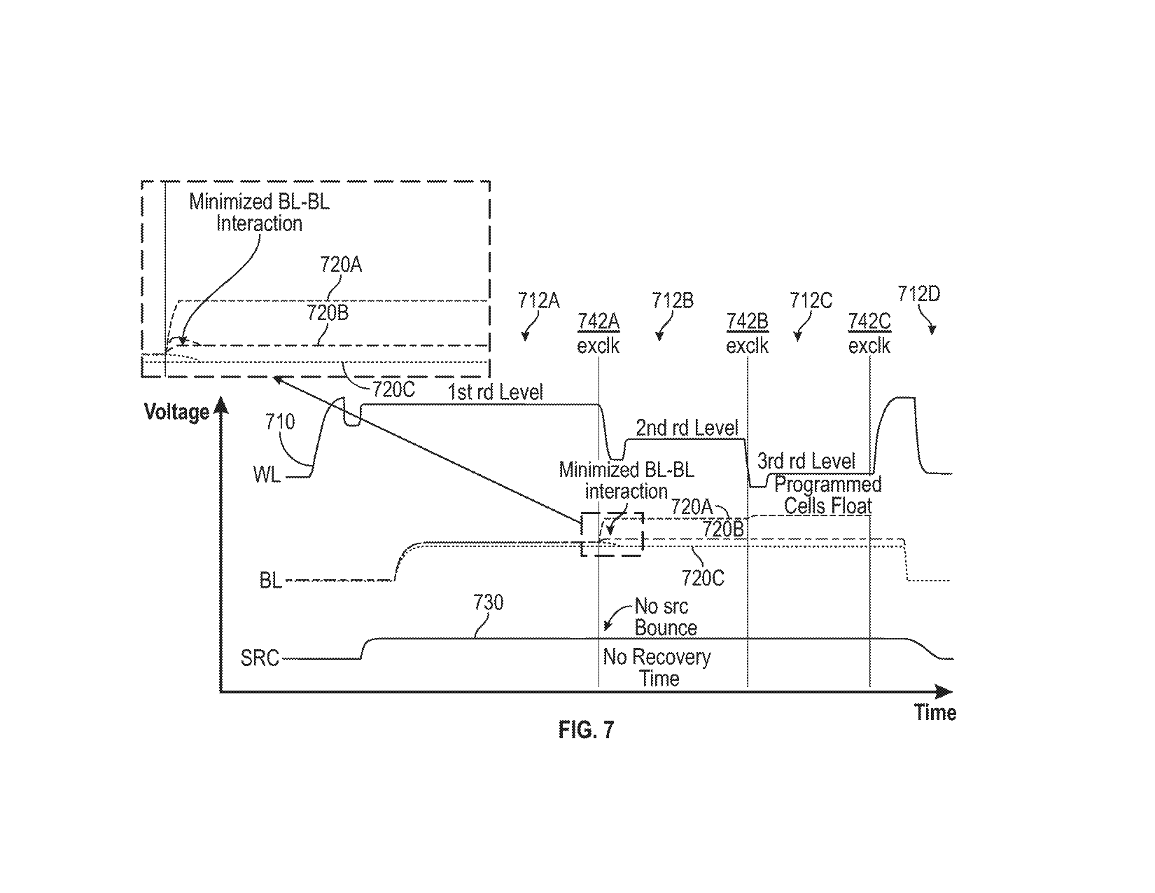

After the data lines (e.g., data line 604) are pre-charged, the memory controller can cause data sensing operations to be performed. For example, the memory controller can cause the sense amplifier 640 to sense, at a first sensing level, data line 604 to obtain data stored on a selected memory cell connected to data line 604. A first sensing level corresponds to a first word line voltage level. Turning to FIG. 7 briefly, the first word line voltage level is the first read level 712A, which is applied by the memory controller to the word line of the selected memory cell to be sensed. Also shown in FIG. 7, different sensing levels correspond to different word line voltage levels. For instance, a second sensing level corresponds to the second read level 712B, which has a different word line voltage from the first sensing level 712A. And a third sensing level corresponds to a third read level 712C, which has a yet another different word line voltage from the second or the first sensing levels 712B and 712A, respectively. The memory controller can cause the different word line voltages to be generated (e.g., by using a regulator) and applied to the word line of the selected memory cell being sensed. Transitions from one sensing level to another and transition from the last sensing level to a recovery phase are triggered by external clock events (e.g., clock events 742A-742C).

With reference to both FIGS. 6 and 7, for performing the data sensing operation of the selected memory cell connected to data line 604 at the first sensing level, the memory controller causes the switch 626 (denoted as blclamp2) to turn off, thereby isolating the data line 604 from the power supply 632. In effect, it cuts off the pull-up path for the data line 604. The memory controller further causes a first read level 712A to be applied to the word line of the selected memory cell in string 610 connected to data line 604. Depending on the threshold voltage of the selected memory cell, data line 604 may or may not conduct current. For example, in a reverse read operation (like the one shown in FIG. 7), if the first read level 712A is less than the threshold voltage of the selected memory cell, the selected memory cell turns off, and no current or a negligible current flows through data line 604. If the first read level 712A is greater than the threshold voltage of the selected memory cell, the selected memory cell turns on or remains on, and current flows through data line 604. The current flowing through data line 604 can be sensed by sense amplifier 640.

With reference still to FIG. 6, to sense the current flowing through data line 604, the memory controller causes the switch 616 to turn on (or remain on). The memory controller further turns on switch 634 such that the current flowing through the data line 604 can be integrated and converted to a voltage at the temporary cache node 636 (denoted by tc) by a capacitive element 638. Capacitive element 638 may be a capacitor or a transistor configured to function as a capacitor. The memory controller may further turn on switches 652, and 644 or 646 depending on if a forward read operation or a reverse read operation is performed respectively. Switches 652, 644, and 646 can all be implemented using transistors. If the voltage at the temporary cache node 636 is high, it may turn on switch 654, and therefore pull down the input node 631 or 633 of the sense amplifier 640. The input nodes 631 or 633 of the sense amplifier 640 may also be output nodes. For example, in a forward read operation, node 631 can be the input node to sense amplifier 640 and node 633 can be the output node. In a reverse read operation, node 633 can be the input node while node 631 can be the output node. Therefore, the polarity of input or output of nodes 631 or 633 may be exchanged depending on the type of read operations. In one example as shown in FIG. 6, the sense amplifier 640 can include a cross-coupled inverter pair 642. The cross-coupled inverter configuration improves the sensitivity of the sense amplifier 640. If the input node 631 of the cross-coupled inverter pair 642 is pulled down to a low voltage (e.g., at the source plate voltage or a ground voltage), the output of the sense amplifier 640 may be at a high voltage by inverting the low input voltage. Thus, in a reverse read operation, if the first read level 712A is greater than the threshold voltage of the selected memory cell connected to data line 604, the output of the sense amplifier can be a high voltage (e.g., SA=1). Conversely, if the first read level 712A is less than the threshold voltage of the selected memory cell connected to data line 604, the output node 633 of the sense amplifier 640 can be a low voltage (e.g., SA=0). The data sensing operation can therefore be performed by using a memory controller and circuit 600, and the voltage of the output node 633 of the sense amplifier 640 can be provided to a data latch (e.g., data latch 244 shown in FIG. 2C). For instance, the memory controller can turn on the switch 646 (and turn off the switches 648 and 652) to provide the sensed voltage stored at the output node 633 to a data latch (not shown in FIG. 6). While the above description of data sensing operation performed at the first sensing level uses data line 604 as an example, it is understood that similar data sensing operations can be performed with respect to other data lines (e.g., data line 602) in a similar manner by one or more sense amplifiers. The first sensing results obtained from these data sensing operations can be stored in data latches.

With reference still to FIGS. 6 and 7, in some examples, the memory controller is further configured to determine, based on the first sensing result provided by the sense amplifiers, a first subgroup of data lines to be sensed at the second sensing level. As described above, if the memory controller determines that a particular selected memory cell has a threshold voltage that satisfies the first sensing level (e.g., corresponding to the first word line voltage level or the first read level), the memory controller may have obtained the data stored in the selected memory cell and thus there is no need to perform additional data sensing operations on the selected memory cell. Otherwise, the memory controller can continue to perform data sensing operations at the next sensing level. In a reverse read operation, for example, if the sense amplifier output is a high voltage (e.g., SA=1) at the first sensing level, the memory controller can determine that a next data sensing operation should be performed; and vice versa.

Conventionally, as described above, if the next data sensing operation is not needed, the corresponding data line may be knocked-out. However, knock-out may cause interference of adjacent data lines and disturbance of the source plate, thereby reducing the data sensing performance. In this disclosure, even if the memory controller determines that a particular data line is not to be sensed at the next sensing level, the memory controller is configured to keep the data line pre-charged. With reference to FIGS. 6 and 7, for instance, after sensing the data line 604 at the first sensing level, the memory controller may determine that data line 604 need not be sense again (e.g., because the sense amplifier output is a low voltage, or SA=0). Nonetheless, the memory controller may still keep data line 604 per-charged, by turning off the switches 634 and turning back on the switch 626. Because switch 616 remains on, the data line 604 is again pulled up to the voltage of the power supply 632 (e.g., VCC). As such, no knock-out of the data line occurs. It is understood that other data lines that have been determined not to be sensed at the second sensing level can be similarly pulled up and kept pre-charged to avoid knock-out.

FIG. 7 illustrates a timing diagram illustrating read operations performed by circuits configured to reduce or avoid data line knock-out by keeping the data lines pre-charged even if some data lines are not sensed at the next sensing levels, in accordance with examples as disclosed herein. As shown in FIG. 7, because there is no data line knock out, the voltage levels of the adjacent data lines (e.g., bit lines 720B and 720C, which are adjacent to a bit line that is determined not to be sensed at the second sensing level such as second read level 712B) do not have interference or have only minimum/reduced interference. FIG. 7 also shows another data line 720A, which is a bit line connected to a memory cell having a threshold voltage (Vth) that is lower than the first read level 712A but higher than the second read level 712B. As a result, data line 720A moves when the read level changes (e.g., word line voltage changes). In this case, regardless of the memory cell’s threshold voltage level or if it should be sensed again at the next level, the associated data line (e.g., data line 720A) is not knocked out. Instead, it is again pre-charged or remain pre-charged. In FIG. 7, data line 720A is pre-charged during the second read level 712B and remain pre-charged during the third read level 712C, even if its associated memory cell is not sensed at the third read level 712C.

With reference to FIGS. 6 and 7, data sensing operations can be repeated to obtain additional data stored in the memory cells connected to the first subgroup of data lines that have been determined to be sensed at the second sensing level (e.g., second read level 712B). And the above-describe process can be repeated such that the memory controller determines, based on a second sensing result provided by the sense amplifers, a second subgroup of the data lines to be sensed at the third sensing level (e.g., third read level 712C). The memory controller keeps the data lines pre-charged even if some data lines in the first subgroup need not be sensed at the third sensing level. The memory controller can cause the sense amplifiers to sense, at the third sensing level, the second subgroup of data lines to obtain another additional data stored on the selected memory cells; and keep the data lines pre-charged even if at least some data lines of the second subgroup need not be sensed at a next sensing level. The process can thus repeat as many times as needed and the data lines are kept pre-charged to avoid knock-out, even if memory cells associated with these data lines are not sensed at the next sensing level. Further, as shown in FIG. 7, by avoiding knock-out, the source plate 730 (e.g., corresponding to SRC 622) has no or minimum source voltage changes (e.g., no source bounce). As such, the next data sensing operation can be performed without waiting (or with much reduced time delay) for the source plate 730 to recover and/or without waiting (or with much reduced time delay) for the adjacent data lines to recover. As a result, the speed of the data sensing operations can be improved and the accuracy of the data sensing operations can also be improved due to the stability of the data lines.

As shown in FIG. 7, after data sensing operations are completed for the data lines connected to the selected memory cells at all sensing levels, the word line voltage 710 is reduced to the low level 712D in the recovery phase. And the memory controller causes discharging of the data lines (e.g., all bit lines 720A-720C are discharged to the source plate after the external clock event 742C). The other external clock events 742A and 742B are used to trigger the transitions of the sensing levels.

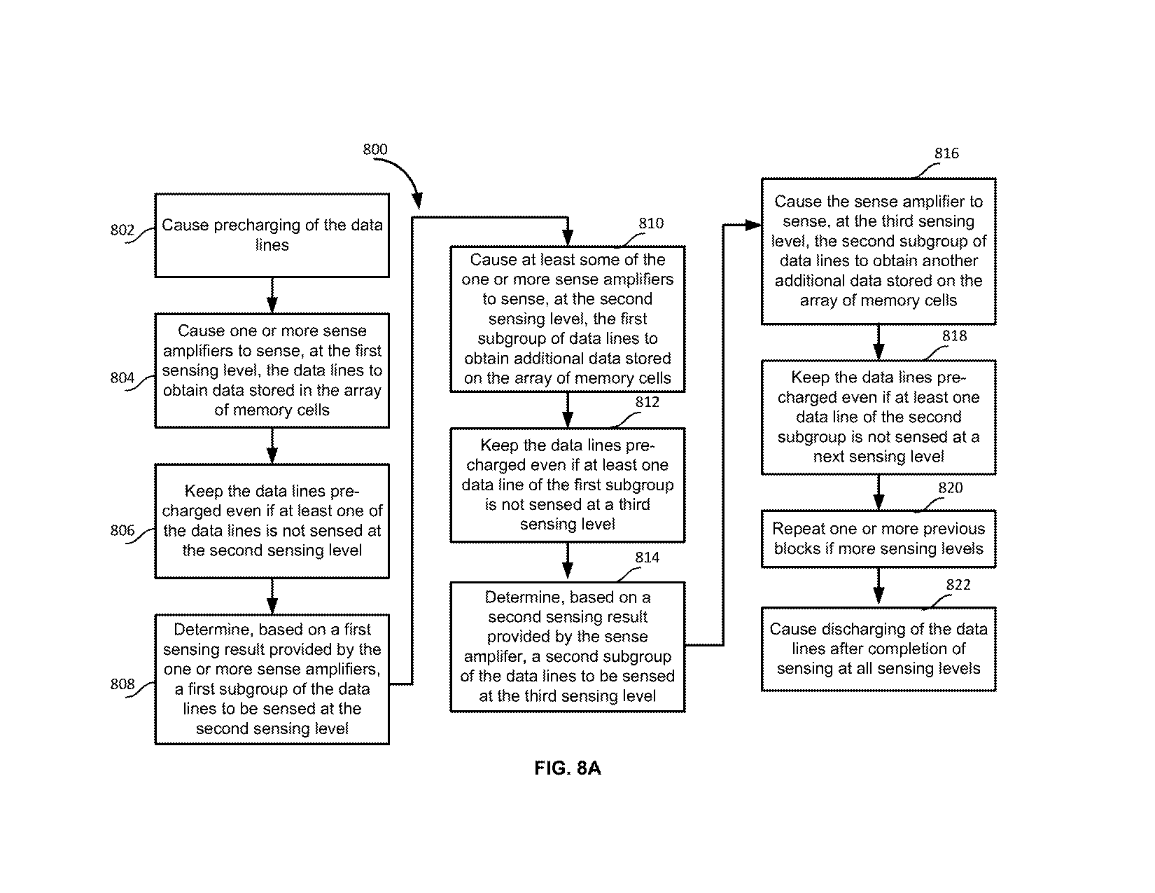

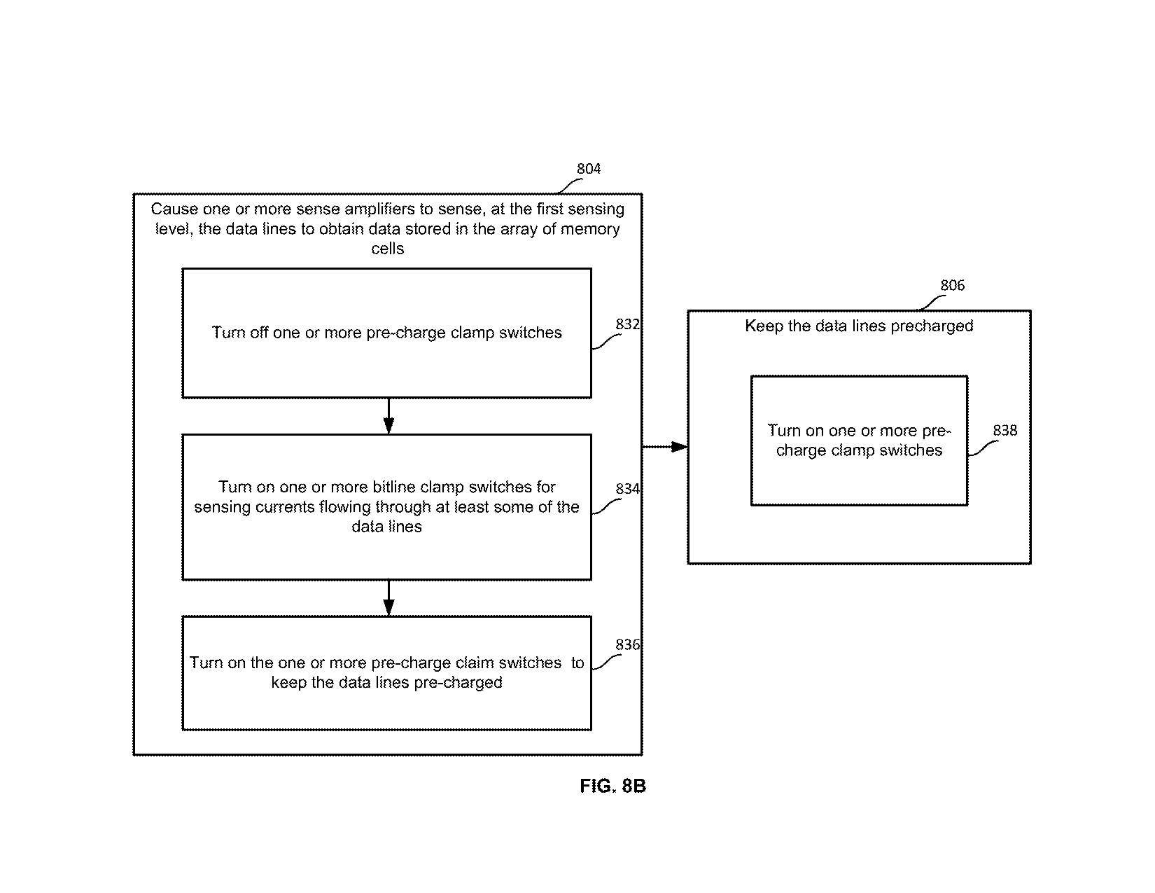

FIGS. 8A and 8B illustrate flowcharts showing a method or methods that support techniques for reducing data line interference due to knock-out in accordance with examples as disclosed herein. The method 800 shown in FIGS. 8A and 8B can be performed by a memory device including a controller, an array of memory cells and data lines coupled to the array of memory cells (e.g., local controller 135). The method 800 can be for data sensing operations comprising sensing at least at a first sensing level and a second sensing level. In some examples, the data sensing operations comprise a read operation or a program verification operation. For example, the data sensing operation may be a reverse read operation such that the first sensing level if greater than the second sensing level. The data sensing operation may be a forward read operation such that the first sensing level is less than the second sensing level. In general, the data sensing operations can comprise sensing at a plurality of different sensing levels (e.g., 1^{st}, 2^{nd}, and 3^{rd} levels representing different word line voltages. At each data sensing level, a single sensing operation is performed. Thus, for a TLC memory cell, the data sensing operations may be performed at 7 different levels, and for a QLC memory cell, the data sensing operations may be performed at 15 different levels. At different data sensing levels, the memory controller can apply different word line voltage levels to word lines of one or more memory cells during corresponding data sensing operations.

At block 802 of method 800, the memory controller causes precharging of the data lines. As described above in connection with FIG. 6, the precharging can be performed by controlling certain switches (e.g., switches 616 and 626) to turn on, thereby enabling a pull up path to precharge the data lines to a power supply voltage (e.g., VCC). At block 804, the memory controller causes the one or more sense amplifiers (e.g., sense amplifier 640) to sense, at the first sensing level, the data lines to obtain data stored in the array of memory cells. As described above, for example, sense amplifier 640 can be controlled to sense, at a first sensing level (e.g., first read level 712A in FIG. 7), bit line 604 to obtain data stored in a selected memory cell of string 610.

With reference still to FIG. 8A, at block 806, the memory controller further keeps the data lines pre-charged even if at least one of the data lines is not sensed at the second sensing level. For instance, in FIG. 6, even if bit line 604 is not sensed at the second sensing level (e.g., second read level 712B), the memory controller can keep the bit line 604 pre-charged by enabling the pull up path again to keep the voltage of bit line 604 at the power supply voltage (e.g., VCC).

At block 808, in one example, the memory controller further determines, based on a first sensing result provided by the one or more sense amplifiers, a first subgroup of the data lines to be sensed at the second sensing level. As described above, if SA=1, for example, it means the selected memory cells has a threshold voltage that is greater than the first sensing level. Using bit line 602 in FIG. 6 as an example, the selected memory cell coupled to string 608 may need to be sensed at the second sensing level, and therefore, bit line 602 is a part of the first subgroup.

At block 810, the memory controller causes at least some of the one or more sense amplifiers to sense, at the second sensing level, the first subgroup of data lines to obtain additional data stored on the array of memory cells. Continuing with the above example, the selected memory cell of string 608 coupled to bit line 602 is sensed at the second sensing level because the first sensing level did not satisfy the threshold voltage of the selected memory cell.

At block 812, the memory controller keeping the data lines pre-charged even if at least one data line of the first subgroup is not sensed at a third sensing level. Again, using bit line 602 as an example, even if the selected memory cell of string 608 coupled to bit line 602 should not be sensed at the third sensing level (e.g., because the second sensing level already satisfied the threshold voltage of the selected memory cell), the controller can still keep bit line 602 pre-charged. Therefore, regardless of SA=0 or 1, the bit lines are pre-charged to avoid knock out.

The process can be repeated. For example, at block 814, the memory controller determines, based on a second sensing result provided by the sense amplifier, a second subgroup of the data lines to be sensed at the third sensing level. For example, if SA=1, it means the selected memory cells has a threshold voltage that is greater than the second sensing level. Therefore, the bit line coupled to the selected memory cell is a part of the second subgroup of data lines to be sensed at the third sensing level.

At block 816, the memory controller causes the sense amplifier to sense, at the third sensing level, the second subgroup of data lines to obtain another additional data stored on the array of memory cells. At block 818, the memory controller keeps the data lines pre-charged even if at least one data line of the second subgroup is not sensed at a next sensing level.

At block 820, the one or more previous blocks can be repeated if there are more data sensing levels. At block 822, the memory controller causes discharging of the data lines after completion of sensing at all sensing levels.

Turning to FIG. 8B, in one example, the memory controller causes (at block 804) the sense amplifier to sense, at the first sensing level, the data lines by the following process. At block 832, the memory controller can turn off one or more pre-charge clamp switches (e.g., switch 626 denoted by blclamp 2 ). At block 834, the memory controller can turn on one or more bitline clamp switches (e.g., switch 616 denoted as blclamp) for sensing currents flowing through at least some of the data lines. At block 836, the memory controller can cause the sense amplifier (e.g., amplifier 640) to sense a voltage based on an integration of the currents flowing through at least some of the data lines via a capacitive element (e.g., the tc node 636 voltage).

FIG. 8B also illustrates that, in one example, the memory controller keeps (at block 806) the data line pre-charged by turning on (block 838) one or more precharge clamp switches (e.g., switch 626 denoted by blclamp 2).

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells;
data lines coupled to the array of memory cells;
one or more sense amplifiers coupled to the data lines; and
a memory controller configured to perform, for data sensing operations comprising sensing at least at a first sensing level and a second sensing level:
causing precharging of the data lines,
causing the one or more sense amplifiers to sense, at the first sensing level, the data lines to obtain data stored in the array of memory cells, and
keeping the data lines pre-charged even if at least one of the data lines is not sensed at the second sensing level.

2. The memory device of claim 1, wherein the data sensing operations comprise a read operation or a program verification operation.

3. The memory device of claim 1, wherein the data sening operations comprise:
a reverse read operation such that the first sensing level if greater than the second sensing level; or
a forward read operation such that the first sensing level is less than the second sensing level.

4. The memory device of claim 1, wherein the data sensing operations comprise sensing at a plurality of different sensing levels, the pulrality of different sensing levels including the first sensing level and the second sensing level.

5. The memory device of claim 4, wherein the plurality of different sensing levels corresponds to different word line voltage levels, and wherein the memory controller is further configured to perform:
applying the different word line voltage levels to word lines of one or more of the array of memory cells during corresponding data sensing operations.

6. The memory device of claim 1, wherein the memory controller is further configured to perform:
determining, based on a first sensing result provided by the one or more sense amplifers, a first subgroup of the data lines to be sensed at the second sensing level;
causing at least some of the one or more sense amplifiers to sense, at the second sensing level, the first subgroup of data lines to obtain additional data stored on the array of memory cells; and
keeping the data lines pre-charged even if at least one data line of the first subgroup is not sensed at a third sensing level.

7. The memory device of claim 6, wherein the memory controller is further configured to perform:
determining, based on a second sensing result provided by the sense amplifer, a second subgroup of the data lines to be sensed at the third sensing level;
causing the sense amplifier to sense, at the third sensing level, the second subgroup of data lines to obtain another additional data stored on the array of memory cells; and
keeping the data lines pre-charged even if at least one data line of the second subgroup is not sensed at a next sensing level.

8. The memory device of claim 1, wherein the causing the sense amplifier to sense, at the first sensing level, the data lines comprises:
turning off one or more pre-charge clamp switches;
turning on one or more bitline clamp switches for sensing currents flowing through at least some of the data lines; and
causing the sense amplifier to sense a voltage based on an integration of the currents flowing through at least some of the data lines via a capacitive element.

9. The memory device of claim 8, wherein keeping the data lines pre-charged comprises: turning on the one or more pre-charge claim switches to keep the data lines pre-charged.

10. The memory device of claim 1, wherein the memory controller is further configured to perform:
causing discharging of the data lines after completion of sensing at all sensing levels.

11. The memory device of claim 10, wherein the data lines are discharged to a voltage level of a source plate, the source plate being coupled to the data lines and the voltage level of the source plate is regulated.

12. The memory device of claim 1, wherein the data lines are bit lines.

13. A memory system comprising:
a memory device comprising:
an array of memory cells;
data lines coupled to the array of memory cells;
one or more sense amplifiers coupled to the data lines; and
a memory controller configured to perform, for data sensing operations comprising sensing at least at a first sensing level and a second sensing level:
causing precharging of the data lines,
causing the one or more sense amplifiers to sense, at the first sensing level, the data lines to obtain data stored in the array of memory cells, and
keeping the data lines pre-charged even if at least one of the data lines is not sensed at the second sensing level.

14. A method performed by a memory device, the memory device comprising an array of memory cells, a controller, and data lines coupled to the array of memory cells, the method comprising, for data sensing operations comprising sensing at least at a first sensing level and a second sensing level:
causing precharging of the data lines;
causing the one or more sense amplifiers to sense, at the first sensing level, the data lines to obtain data stored in the array of memory cells; and
keeping the data lines pre-charged even if at least one of the data lines is not sensed at the second sensing level.

15. The method of claim 14, wherein the data sensing operations comprise a read operation or a program verification operation.

16. The method of claim 14, wherein the data sening operations comprise:
a reverse read operation such that the first sensing level if greater than the second sensing level; or
a forward read operation such that the first sensing level is less than the second sensing level.

17. The method of claim 14, wherein the data sensing operations comprise sensing at a plurality of different sensing levels, the pulrality of different sensing levels including the first sensing level and the second sensing level.

18. The method of claim 17, wherein the plurality of different sensing levels corresponds to different word line voltage levels, further comprising:
applying the different word line voltage levels to word lines of one or more of the array of memory cells during corresponding data sensing operations.

19. The method of claim 14, further comprising:
determining, based on a first sensing result provided by the one or more sense amplifiers, a first subgroup of the data lines to be sensed at the second sensing level;
causing at least some of the one or more sense amplifiers to sense, at the second sensing level, the first subgroup of data lines to obtain additional data stored on the array of memory cells; and
keeping the data lines pre-charged even if at least one data line of the first subgroup is not sensed at a third sensing level.

20. The method of claim 19, further comprising:
determining, based on a second sensing result provided by the sense amplifier, a second subgroup of the data lines to be sensed at the third sensing level;
causing the sense amplifier to sense, at the third sensing level, the second subgroup of data lines to obtain another additional data stored on the array of memory cells; and
keeping the data lines pre-charged even if at least one data line of the second subgroup is not sensed at a next sensing level.

21. The method of claim 14, wherein the causing the sense amplifier to sense, at the first sensing level, the data lines comprises:
turning off one or more pre-charge clamp switches;
turning on one or more bitline clamp switches for sensing currents flowing through at least some of the data lines; and
causing the sense amplifier to sense a voltage based on an integration of the currents flowing through at least some of the data lines via a capacitive element.

22. The method of claim 21, wherein keeping the data lines pre-charged comprises: turning on the one or more pre-charge claim switches to keep the data lines pre-charged.

23. The method of claim 14, further comprising:
causing discharging of the data lines after completion of sensing at all sensing levels.

24. The method of claim 23, wherein the data lines are discharged to a voltage level of a source plate, the source plate being coupled to the data lines and the voltage level of the source plate is regulated.
